(19) United States
(12) Patent Application Publication
(10) Pub. No.: US 2026/0101545 A1
(43) Pub. Date: Apr. 9, 2026

(54) INTEGRATED CIRCUIT PACKAGES AND METHODS

(71) Applicant: Taiwan Semiconductor Manufacturing Co., Ltd., Hsinchu (TW)

(72) Inventors: Chen-Shien Chen, Zhubei City (TW); Hsu-Hsien Chen, Hsinchu (TW); Yao-Chun Chuang, Hsinchu (TW); Jyun-Lin Wu, Hsinchu (TW)

(21) Appl. No.: 18/908,893

(22) Filed: Oct. 8, 2024

(51) Int. Cl. H01L 29/06; H01L 21/266; H01L 21/768; H01L 23/31; H01L 23/522; H01L 23/58; H01L 25/00; H01L 25/10

(52) U.S. Cl. CPC H10D 62/106; H10W 42/00; H10W 74/141; H10P 30/22; H10W 20/031; H10W 20/40; H10W 90/00; H10W 90/722

(57) ABSTRACT

An integrated circuit package and the method of forming the same are provided. The integrated circuit package may include an integrated circuit die and a dielectric material on sidewalls of the integrated circuit die. The integrated circuit die may include a substrate, a protective structure in the substrate, an interconnect structure on the substrate, and a seal ring structure in the interconnect structure and in contact with the protective structure. The protective structure and the substrate may include a same semiconductor material, and the protective structure may include a first dopant and a second dopant different from the first dopant. The interconnect structure may include dielectric layers and conductive features in the dielectric layers. The seal ring structure may encircle the conductive features of the interconnect structure in a top-down view.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5A, 5B, and 5C illustrate various views of intermediate steps during a process for forming an integrated circuit die, in accordance with some embodiments.

FIGS. 6A, 6B, and 6C illustrate various views of an integrated circuit die, in accordance with some embodiments.

FIGS. 7A, 7B, and 7C illustrate various views of a dummy die, in accordance with some embodiments.

FIGS. 8, 9, 10, 11, 12, 13, 14, 15, and 16 illustrate various views of intermediate steps during a process for forming an integrated circuit package, in accordance with some embodiments.

FIGS. 17A, 17B, 17C, and 18 illustrate various views of an integrated circuit die and an integrated circuit package comprising the integrated circuit die, in accordance with some embodiments.

FIGS. 19A, 19B, 19C, and 20 illustrate various views of an integrated circuit die and an integrated circuit package comprising the integrated circuit die, in accordance with some embodiments.

FIGS. 21A, 21B, 21C, and 22 illustrate various views of an integrated circuit die and an integrated circuit package comprising the integrated circuit die, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit package comprises an integrated circuit die in one tier as well as another integrated circuit die and an inactive die in another tier. Gap-fill dielectrics may be formed around the integrated circuit dies and the inactive die. The integrated circuit dies and the inactive dies may comprise protective structures that separate seal ring structures from substrates. The protective structures may reduce or prevent electrostatic charges generated in the substrates from being released through the seal ring structures, thereby reducing or preventing formation of cracks due to electrostatic discharge (ESD) in the integrated circuit dies, the inactive die, and/or the gap-fill dielectrics. As a result, the reliability of the integrated circuit package may be improved.

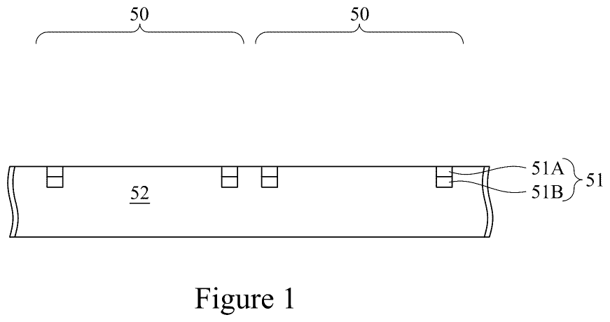

FIGS. 1, 2, 3, 4, 5A, 5B, and 5C illustrate various views of intermediate steps during a process for forming an integrated circuit die 50, in accordance with some embodiments. In FIG. 1, protective structures 51 are formed in a wafer 52. The wafer 52 and features that may be may formed on the wafer 52 may be subsequently singulated to form discrete integrated circuit dies 50 as described below in greater details. Regions in the wafer 52 where the integrated circuit dies 50 may be formed are shown as the integrated circuit dies 50 for illustrative purposes. After the singulation process, the wafer 52 may form substrates 52, which may be parts of the integrated circuit dies 50. The protective structures 51 may comprise p-n junctions and may be referred to as diodes. The protective structures 51 may reduce or prevent formation of cracks due to electrostatic discharge (ESD) in and around the integrated circuit dies 50 as discussed in greater details below.

The wafer 52 may comprise a semiconductor material, such as silicon, germanium, or the like. The wafer 52 and the subsequently formed substrates 52 may have active surfaces (e.g., the surfaces facing upwards in FIG. 1), sometimes referred to as front sides, and inactive surfaces (e.g., the surfaces facing downwards in FIG. 1), sometimes referred to as back sides. Devices (not separately illustrated) may be disposed at the active surface of the wafer 52. The devices may be transistors, capacitors, resistors, or the like, and may be parts of the integrated circuit dies 50 after the subsequent singulation process.

In the embodiments illustrated in FIG. 1, the protective structures 51 comprise first portions 51A and second portions 51B. Surfaces of the first portions 51A may be exposed and may be co-planar with the active surface of the wafer 52. The first portions 51A may comprise a first dopant and the second portions 51B may comprise a second dopant. The first dopant may be different from the second dopant. The first dopant and the second dopant may be of different conductivity types, and p-n junctions may be formed at interfaces between the first portions 51A and the second portions 51B. In some embodiments, the first dopant may be an n-type dopant, such as phosphor, arsenic, or the like, and the second dopant may be a p-type dopant, such as boron, aluminum, gallium, indium, or the like. In some embodiments, the first dopant may be a p-type dopant, such as boron, aluminum, gallium, indium, or the like, and the second dopant may be an n-type dopant, such as phosphor, arsenic, or the like.

The protective structures 51 may be formed in the wafer 52 by doping portions of the wafer 52. As a result, the protective structures 51 may comprise a same material as the wafer 52. The protective structures 51 may be formed by a masking step and two doping steps. A mask may be formed on the active surface of the wafer 52 using a suitable photolithography process. The pattern of the mask may expose the portions in the wafer 52 wherein the protective structures 51 may be formed and cover the rest of the wafer 52. A first doping step may be performed to form the second portions 51B with the second dopant using a suitable ion implantation process. An annealing process may be done after the ion implantation process. A dopant concentration of the second dopant in the second portions 51B may be in a range from about 1×10¹⁵ cm⁻³ to about 1×10²⁰ cm⁻³. A second doping step may be performed to form the first portions 51A with the first dopant using a suitable ion implantation process. An annealing process may be done after the ion implantation process. A dopant concentration of the first dopant in the first portions 51A may be in a range from about 1×10¹⁵ cm⁻³ to about 1×10²⁰ cm⁻³.

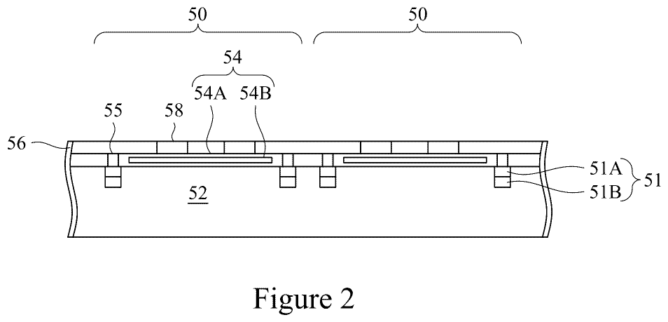

In FIG. 2, interconnect structures 54 are formed on the active surface of the wafer 52, seal ring structures 55 are formed in the interconnect structures 54, a dielectric layer 56 is formed on the interconnect structures 54, and die connectors 58 are formed in the dielectric layer 56. The interconnect structures 54 may interconnect the devices at the active surface of the wafer 52 (e.g., the substrates 52) to form circuitry in the subsequently formed integrated circuit dies 50. The interconnect structure 54 may comprise dielectric layers 54A and conductive features 54B in dielectric layers 54A. The dielectric layers 54A may be formed by suitable deposition processes, such as chemical vapor deposition (CVD), atomic layer deposition (ALD), or the like. The conductive features 54B may include metal lines and vias, which may be formed in the dielectric layers 54A by damascene processes, such as single damascene processes, dual damascene processes, or the like. The conductive features 54B may be formed of a suitable conductive material, such as copper, tungsten, aluminum, silver, gold, or the like. The conductive features 54B may be electrically coupled to the devices at the active surface of the wafer 52. The seal ring structures 55 may include conductive lines and vias, which may be formed by same or similar processes and formed of a same or similar material as the conductive features 54B. The seal ring structures 55 may be electrically isolated from the conductive features 54B and the devices at the active surface of the wafer 52. The seal ring structures 55 may extend through the interconnect structures 54 and contact the protective structures 51.

The dielectric layer 56 may be formed on the interconnect structure 54 by a suitable deposition process such as CVD, ALD, or the like. The dielectric layer 56 may comprise silicon oxide, silicon nitride, or the like. The die connectors 58 may be formed in the dielectric layer 56 by a damascene process, such as a single damascene process, a dual damascene process, or the like. The die connectors 58 may extend through the dielectric layer 56. The die connectors 58 may be formed of a conductive material, such as copper, aluminum, or the like. The dielectric layer 56 and the die connectors 58 may be used in a subsequent bonding process to bond the integrated circuit dies 50 to other features.

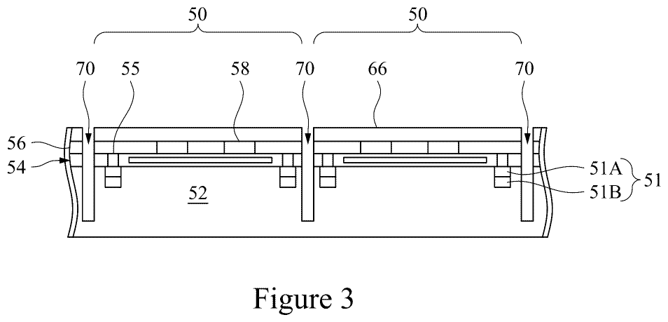

In FIG. 3, a mask 66 is formed on the dielectric layer 56 and the die connectors 58, and openings 70 are through the portions of the wafer 52 exposed by the mask 66. The mask 66 may be a photoresist and may be formed by spin coating or the like and patterned by a suitable photolithography process. The openings 70 may be formed through the portions of the wafer 52 exposed by the mask 66 by a suitable dicing process. In some embodiments, the dicing process is a mechanical dicing process using a saw or the like. In some embodiments, the dicing process is chemical dicing process using a suitable plasma source. After the dicing process, the mask 66 may be removed using an acceptable ashing or stripping process.

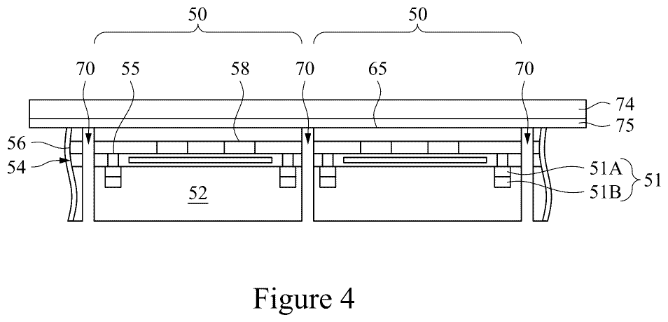

In FIG. 4, the structure shown in FIG. 3 is attached to a carrier 74 by an adhesive 75 and the wafer 52 is thinned on the inactive surface. The carrier 74 may be a semiconductor carrier, a glass carrier, a ceramic carrier, or the like. The carrier 74 may be a wafer. In some embodiments, the adhesive 75 is a thermal-release layer, such as an epoxy-based light-to-heat-conversion (LTHC) release material, which loses its adhesive property when heated. In some embodiments, the adhesive 75 is a UV glue, which loses its adhesive property when exposed to UV light. Then a thinning process is performed on the inactive surface of the wafer 52, which results in the singulation of the structure shown in FIG. 3 and the formation of the integrated circuit dies 50. The thinning process may be performed using a chemical-mechanical polish (CMP), a grinding process, an etch-back process, the like, or a combination thereof, which may remove portions of the wafer 52 until the openings 70 are exposed on the inactive surface of the wafer 52. As a result, the wafer 52 may be singulated into the discrete substrates 52, which may be parts of the integrated circuit dies 50. A cleaning process or rinsing process may be performed after the thinning process. Then the integrated circuit dies 50 may be detached from the carrier 74.

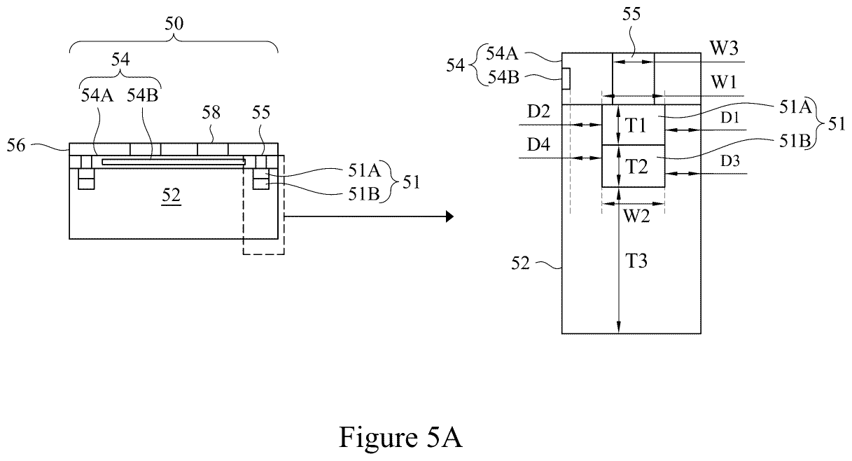

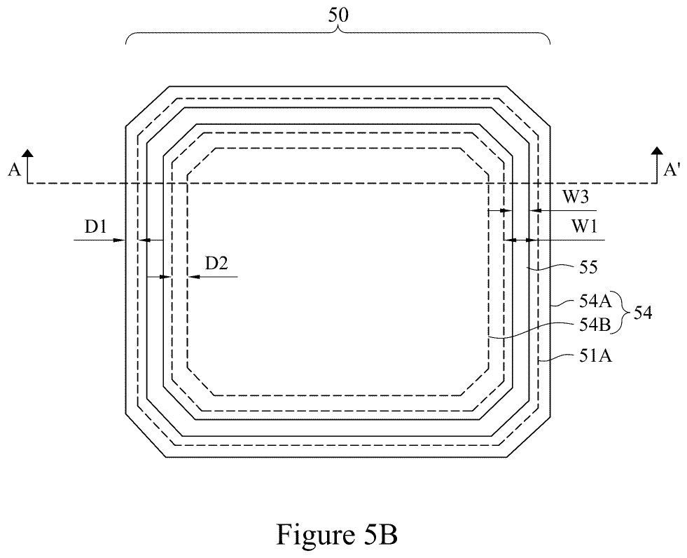

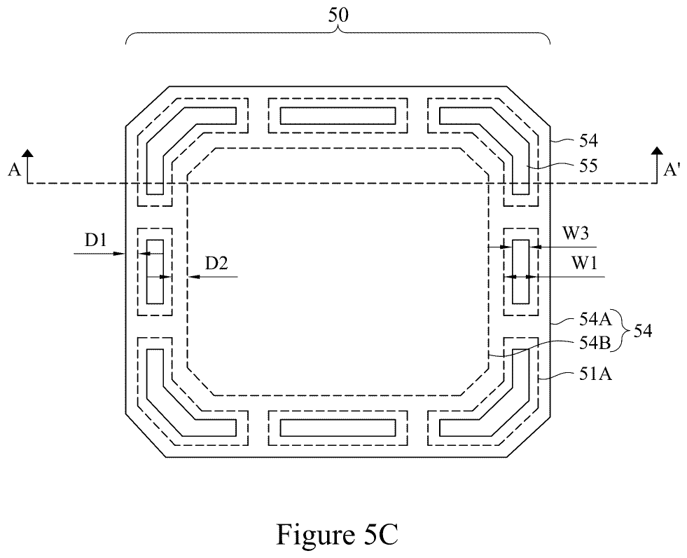

In FIGS. 5A and 5B, one singulated integrated circuit die 50 is shown. FIG. 5A is a cross-sectional view and FIG. 5B is a top-down view. The cross-sectional view in FIG. 5A may be along a reference cross-sections A-A′ shown in the top-down view of FIG. 5B. The conductive features 54B of the interconnect structure 54 and the protective structure 51 are shown in dashed lines in FIG. 5B for illustrative purposes. A portion of the integrated circuit die 50 circled by dashed lines is magnified in FIG. 5A to shown more structural details. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may include the substrate 52, the interconnect structure 54 on the active surface of the substrate 52, the dielectric layer 106 on the interconnect structure 104, and the die connectors 108 in the dielectric layer 106. The protective structure 51 may be disposed in the substrate 52 and the surface of the first portion 51A of the protective structure 51 may be co-planar with the active surface of the substrate 52. The interconnect structure 54 may comprise the dielectric layers 54A and the conductive features 54B in the dielectric layers 54A. The seal ring structure 55 may be disposed in the interconnect structure 54. The seal ring structure 55 may extend through the dielectric layers 54A and contact the first portion 51A of the protective structure 51. The first portion 51A may be between the seal ring structure 55 and the second portion 51B of the protective structure 51. The first portion 51A may separate the seal ring structure 55 from the second portion 51B. In the embodiments shown in FIG. 5B, the seal ring structure 55 is a continuous ring encircling the conductive features 54B and the protective structure 51 is a continuous ring encircling the conductive features 54B in the top-down view. The seal ring structure 55 and the protective structure 51 may be isolated from the circuitry of the integrated circuit die 50.

A surface of the seal ring structure 55 may be in contact with the surface of the first portion 51A and the surface of the seal ring structure 55 may be narrower than the surface of the first portion 51A. The surface of the first portion 51A may be in contact with the dielectric layers 54A. As a result, the surface of the seal ring structure 55 in contact with the protective structure 51 may be completely covered and separated from the substrate 52 by the first portion 51A of the protective structure 51. Electrostatic charges may be generated in the substrate 52 during the formation of the integrated circuit die 50 and in subsequent processes where the integrated circuit die 50 may be used to form an integrated circuit package. The protective structure 51, which may comprise a p-n junction at the interface between the first portion 51A and the second portion 51B, may reduce or prevent the electrostatic charges from being released through the conductive seal ring structure 55, thereby reducing or preventing the formation of cracks due to ESD in and around the integrated circuit die 50.

The first portion 51A may have a width W1 in a range from about 0.1 μm to about 50 μm. The second portion 51B may have a width W2 in a range from about 0.1 μm to about 50 μm. In some embodiments, the width W1 is equal to the width W2. The seal ring structure 55 may have a width W3 in a range from about 0.1 μm to about 45 μm. In some embodiments, the width W1 and the width W2 are larger than the width W3. The first portion 51A may have a thickness T1 in a range from about 0.1 μm to about 20 μm. The second portion 52A may have a thickness T2 in a range from about 0.1 μm to about 20 μm. In some embodiments, the thickness T1 is equal to the thickness T2. The substrate 52 underneath the second portion 51B may have thickness T3 in a range from about 1 μm to about 200 μm. The first portion 51A may be spaced apart from a sidewall of the substrate 52 by a horizontal distance D1 in a range from about 0.1 μm to about 100 μm. The first portion 51A may be spaced apart from the conductive features 54B by a horizontal distance D2 in a range from about 0.1 μm to about 100 μm. The second portion 51B may be spaced apart from the sidewall of the substrate 52 by a horizontal distance D3 in a range from about 0.1 μm to about 100 μm. The second portion 51B may be spaced apart from the conductive features 54B by a horizontal distance D4 in a range from about 0.1 μm to about 100 μm.

FIG. 5C is a top-down view of the integrated circuit die 50 in accordance with some embodiments. The embodiments of the integrated circuit die 50 shown in FIG. 5C may be similar to the embodiments of the integrated circuit die 50 shown in FIG. 5B, wherein like numerals refer to like features formed by like processes. The cross-sectional view in FIG. 5A may be along a reference cross-sections A-A′ shown in the top-down view of FIG. 5C. The conductive features 54B of the interconnect structure 54 and the protective structure 51 are shown in dashed lines in FIG. 5C for illustrative purposes. In the embodiments shown in FIG. 5C, the seal ring structure 55 comprises a fragmented ring encircling the conductive features 54B and the protective structure 51 comprises a fragmented ring encircling the conductive features 54B in the top-down view.

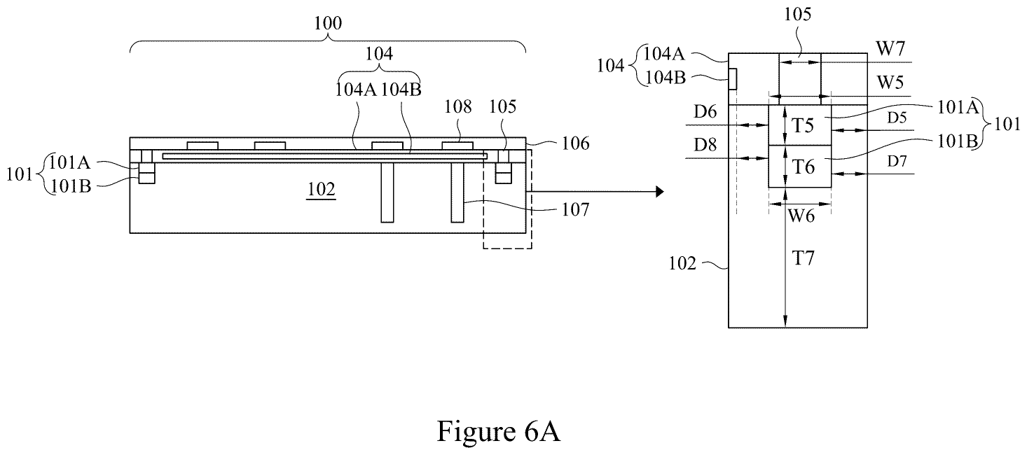

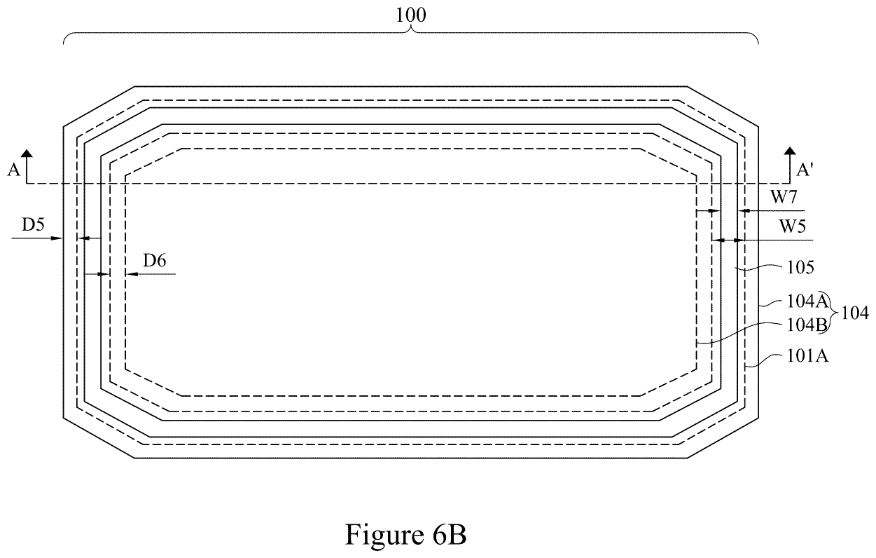

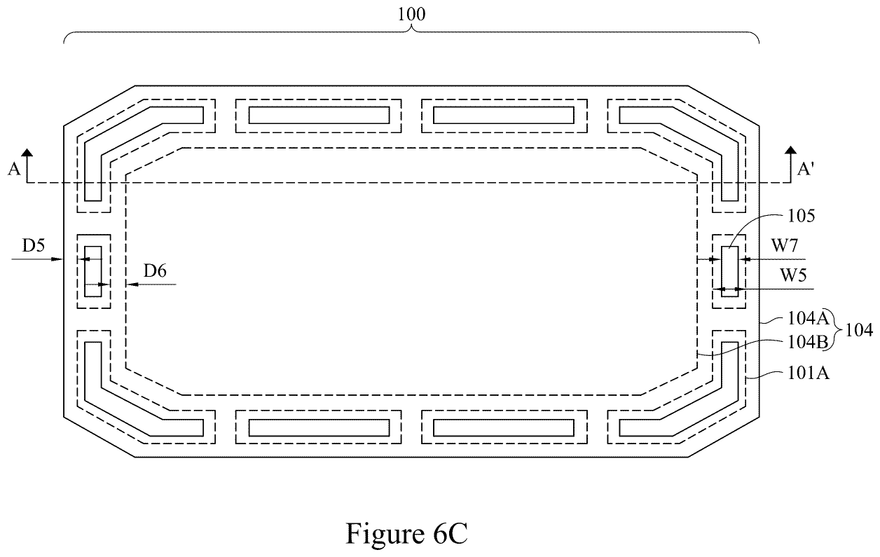

In FIGS. 6A and 6B, an integrated circuit die 100 is shown. FIG. 6A is a cross-sectional view and FIG. 6B is a top-down view. The cross-sectional view in FIG. 6A may be along a reference cross-sections A-A′ shown in the top-down view of FIG. 6B. A portion of the integrated circuit die 100 circled by dashed lines is magnified in FIG. 6A to shown more structural details. The integrated circuit die 100 may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE dies), the like, or combinations thereof.

The materials and formation processes of the features in the integrated circuit die 100 may be found by referring to the like features in the integrated circuit dies 50. The integrated circuit die 100 may include a substrate 102, which may have an active surface (e.g., the surface facing upwards in FIG. 6A), sometimes called a front side, and an inactive surface (e.g., the surface facing downwards in FIG. 6A), sometimes called a back side. Devices (not separately illustrated) may be disposed at the active surface of the substrate 102. The devices may be transistors, capacitors, resistors, etc. A protective structure 101 may be disposed in the substrate 102.

In the embodiments illustrated in FIG. 6A, the protective structure 101 comprises a first portion 101A and a second portion 101B. A surface of the first portion 101A of the protective structure 101 may be co-planar with the active surface of the substrate 102. The first portion 101A may comprise a third dopant and the second portion 101B may comprise a fourth dopant. The third dopant may be different from the fourth dopant. The third dopant and the fourth dopant may be of different conductivity types, and p-n junctions may be formed at an interface between the first portion 101A and the second portion 101B. In some embodiments, the third dopant may be an n-type dopant, such as phosphor, arsenic, or the like, and the fourth dopant may be a p-type dopant, such as boron, aluminum, gallium, indium, or the like. In some embodiments, the third dopant may be a p-type dopant, such as boron, aluminum, gallium, indium, or the like, and the fourth dopant may be an n-type dopant, such as phosphor, arsenic, or the like. A dopant concentration of the third dopant in the first portion 101A may be in a range from about 1×10¹⁵ cm⁻³ to about 1×10²⁰ cm⁻³. A dopant concentration of the fourth dopant in the second portion 101B may be in a range from about 1×10¹⁵ cm⁻³ to about 1×10²⁰ cm⁻³.

An interconnect structure 104 may be on the active surface of the substrate 102. The interconnect structures 104 may interconnect the devices at the active surface of the substrate 102 to form circuitry in the integrated circuit die 100. The interconnect structure 104 may comprise dielectric layers 104A and the conductive features 104B in the dielectric layers 104A. A seal ring structure 105 may be disposed in the interconnect structure 104. The seal ring structure 105 may extend through the dielectric layers 104A and contact the first portion 101A of the protective structure 101. The first portion 101A may be between the seal ring structure 105 and the second portion 101B of the protective structure 101. The first portion 101A may separate the seal ring structure 105 from the second portion 101B. In the embodiments shown in FIG. 6B, the seal ring structure 105 is a continuous ring encircling the conductive features 104B and the protective structure 101 is a continuous ring encircling the conductive features 104B in the top-down view. The conductive features 104B of the interconnect structure 104 and the protective structure 101 are shown in dashed lines in FIG. 6B for illustrative purposes. The seal ring structure 105 and the protective structure 101 may be isolated from the circuitry of the integrated circuit die 100.

A surface of the seal ring structure 105 may be in contact with the surface of the first portion 101A and the surface of the seal ring structure 105 may be narrower than the surface of the first portion 101A. The surface of the first portion 101A may be in contact with the dielectric layers 104A. As a result, the surface of the seal ring structure 105 in contact with the protective structure 101 may be completely covered and separated from the substrate 102 by the first portion 101A of the protective structure 101. Electrostatic charges may be generated in the substrate 102 during the formation of the integrated circuit die 100 and in subsequent processes where the integrated circuit die 100 may be used to form an integrated circuit package. The protective structure 101, which may comprise a p-n junction at the interface between the first portion 101A and the second portion 101B, may reduce or prevent the electrostatic charges from being released through the conductive seal ring structure 105, thereby reducing or preventing formation of cracks due to ESD in and around the integrated circuit die 100.

The first portion 101A may have a width W5 in a range from about 0.1 μm to about 50 μm. The second portion 101B may have a width W6 in a range from about 0.1 μm to about 50 μm. In some embodiments, the width W5 is equal to the width W6. The seal ring structure 105 may have a width W7 in a range from about 0.1 μm to about 45 μm. In some embodiments, the width W5 and the width W6 are larger than the width W7. The first portion 101A may have a thickness T5 in a range from about 0.1 μm to about 20 μm. The second portion 102A may have a thickness T6 in a range from about 0.1 μm to about 20 μm. In some embodiments, the thickness T5 is equal to the thickness T6. The substrate 102 underneath the second portion 101B may have thickness T7 in a range from about 1 μm to about 200 μm. The first portion 101A may be spaced apart from a sidewall of the substrate 102 by a horizontal distance D5 in a range from about 0.1 μm to about 100 μm. The first portion 101A may be spaced apart from the conductive features 104B by a horizontal distance D6 in a range from about 0.1 μm to about 100 μm. The second portion 101B may be spaced apart from the sidewall of the substrate 102 by a horizontal distance D7 in a range from about 0.1 μm to about 100 μm. The second portion 101B may be spaced apart from the conductive features 104B by a horizontal distance D8 in a range from about 0.1 μm to about 100 μm.

The integrated circuit die 100 may include a dielectric layer 106 on the interconnect structure 104 and die connectors 108 in the dielectric layer 106. The integrated circuit die 100 may further include conductive vias 107 in the substrate 102. The conductive vias 107 may be electrically coupled to the conductive features 104B of the interconnect structure 104. The substrate 102 may be thinned in a subsequent process to expose the conductive vias 107 at the inactive surface of the substrate 102. After the thinning process, the conductive vias 107 may be referred to as through-substrate vias (TSVs).

FIG. 6C is a top-down view of the integrated circuit die 100 in accordance with some embodiments. The embodiments of the integrated circuit die 100 shown in FIG. 6C may be similar to the embodiments of the integrated circuit die 100 shown in FIG. 6B, wherein like numerals refer to like features formed by like processes. The cross-sectional view in FIG. 6A may be along a reference cross-sections A-A′ shown in the top-down view of FIG. 6C. The conductive features 104B of the interconnect structure 104 and the protective structure 101 are shown in dashed lines in FIG. 6C for illustrative purposes. In the embodiments shown in FIG. 6C, the seal ring structure 105 comprises a fragmented ring encircling the conductive features 104B and the protective structure 101 comprises a fragmented ring encircling the conductive features 104B in the top-down view.

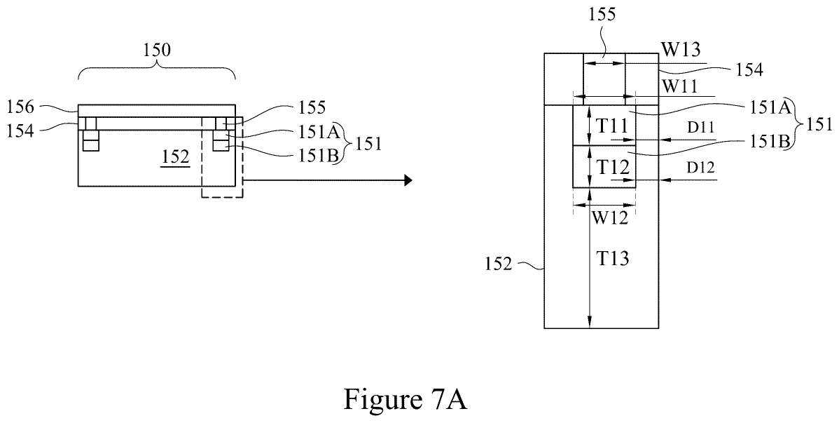

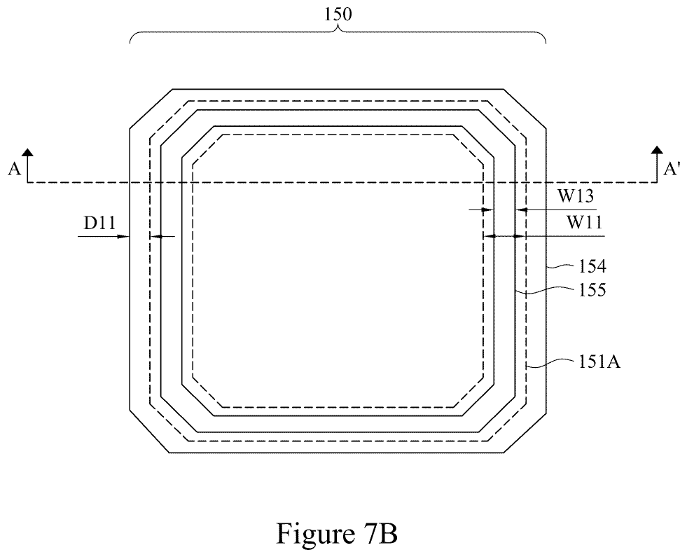

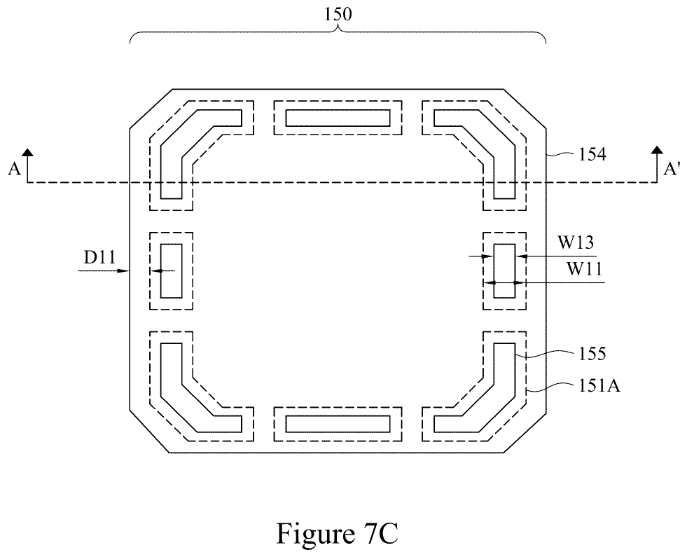

In FIGS. 7A and 7B, an inactive die 150 is shown. FIG. 7A is a cross-sectional view and FIG. 7B is a top-down view. The cross-sectional view in FIG. 7A may be along a reference cross-sections A-A′ shown in the top-down view of FIG. 7B. A portion of the inactive die 150 circled by dashed lines is magnified in FIG. 7A to shown more structural details. The inactive die 150 may be also referred to as a dummy die. The materials and formation processes of the features in the inactive die 150 may be found by referring to the like features in the integrated circuit dies 50. The inactive die 150 may include a substrate 152, which may have a front surface (e.g., the surface facing upwards in FIG. 7A), sometimes called a front side, and a back surface (e.g., the surface facing downwards in FIG. 7A), sometimes called a back side.

In the embodiments illustrated in FIG. 7A, the protective structure 151 comprises a first portion 151A and a second portion 151B. A surface of the first portion 151A of the protective structure 151 may be co-planar with the front surface of the substrate 152. The first portion 151A may comprise a fifth dopant and the second portion 151B may comprise a sixth dopant. The fifth dopant may be different from the sixth dopant. The fifth dopant and the sixth dopant may be of different conductivity types, and p-n junctions may be formed at an interface between the first portion 151A and the second portion 151B. In some embodiments, the fifth dopant may be an n-type dopant, such as phosphor, arsenic, or the like, and the sixth dopant may be a p-type dopant, such as boron, aluminum, gallium, indium, or the like. In some embodiments, the fifth dopant may be a p-type dopant, such as boron, aluminum, gallium, indium, or the like, and the sixth dopant may be an n-type dopant, such as phosphor, arsenic, or the like. A dopant concentration of the fifth dopant in the first portion 151A may be in a range from about 1×10¹⁵ cm⁻³ to about 1×10²⁰ cm⁻³. A dopant concentration of the sixth dopant in the second portion 101B may be in a range from about 1×10¹⁵ cm⁻³ to about 1×10²⁰ cm⁻³.

Dielectric layers 154 may be on the front surface of the substrate 152. A seal ring structure 155 may be disposed in the dielectric layers 154. The seal ring structure 155 may extend through the dielectric layers 154 and contact the first portion 151A of the protective structure 151. The first portion 151A may be between the seal ring structure 155 and the second portion 151B of the protective structure 151. The first portion 151A may separate the seal ring structure 155 from the second portion 151B. In the embodiments shown in FIG. 7B, the seal ring structure 155 is a continuous ring and the protective structure 151 is a continuous ring in the top-down view. The protective structure 151 is shown in dashed lines in FIG. 7B for illustrative purposes.

A surface of the seal ring structure 155 may be in contact with the surface of the first portion 151A and the surface of the seal ring structure 155 may be narrower than the surface of the first portion 151A. The surface of the first portion 151A may be in contact with the dielectric layers 154. As a result, the surface of the seal ring structure 155 in contact with the protective structure 151 may be completely covered and separated from the substrate 152 by the first portion 151A of the protective structure 151. Electrostatic charges may be generated in the substrate 152 during the formation of the inactive die 150 and in subsequent processes where the inactive die 150 may be used to form an integrated circuit package. The protective structure 151, which may comprise a p-n junction at the interface between the first portion 151A and the second portion 151B, may reduce or prevent the electrostatic charges from being released through the conductive seal ring structure 155, thereby reducing or preventing formation of cracks due to ESD in and around the inactive die 150.

The first portion 151A may have a width W11 in a range from about 0.1 μm to about 50 μm. The second portion 151B may have a width W12 in a range from about 0.1 μm to about 50 μm. In some embodiments, the width W11 is equal to the width W12. The seal ring structure 155 may have a width W13 in a range from about 0.1 μm to about 45 μm. In some embodiments, the width W11 and the width W12 are larger than the width W13. The first portion 151A may have a thickness T11 in a range from about 0.1 μm to about 20 μm. The second portion 152A may have a thickness T12 in a range from about 0.1 μm to about 20 μm. In some embodiments, the thickness T11 is equal to the thickness T12. The substrate 152 underneath the second portion 151B may have thickness T13 in a range from about 1 μm to about 200 μm. The first portion 151A may be spaced apart from a sidewall of the substrate 152 by a horizontal distance D11 in a range from about 0.1 μm to about 100 μm. The second portion 151B may be spaced apart from the sidewall of the substrate 152 by a horizontal distance D12 in a range from about 0.1 μm to about 100 μm.

FIG. 7C is a top-down view of the inactive die 50 in accordance with some embodiments. The embodiments of the inactive die 50 shown in FIG. 7C may be similar to the embodiments of the inactive die 50 shown in FIG. 7B, wherein like numerals refer to like features formed by like processes. The cross-sectional view in FIG. 7A may be along a reference cross-sections A-A′ shown in the top-down view of FIG. 7C. The protective structure 51 is shown in dashed lines in FIG. 7C for illustrative purposes. In the embodiments shown in FIG. 7C, the seal ring structure 55 comprises a fragmented ring and the protective structure 51 comprises a fragmented ring in the top-down view.

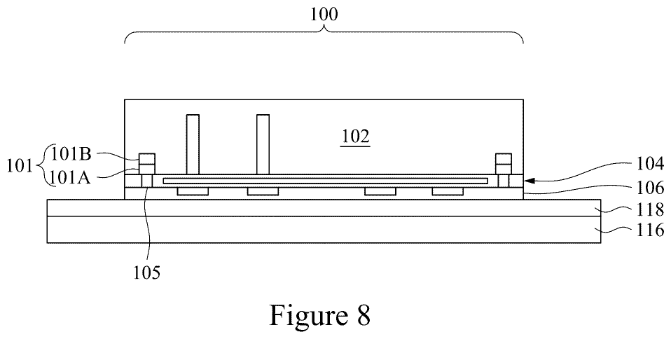

FIGS. 8 through 16 are views of intermediate steps during a process for forming an integrated circuit package 300, in accordance with some embodiments. In FIG. 8, an integrated circuit die 100 is bonded to a carrier 116. The carrier 116 may be a semiconductor carrier, a glass carrier, a ceramic carrier, or the like. The carrier 116 may be a wafer. FIG. 8 illustrates one integrated circuit die 100 bonded to the carrier 116 as an example, two or more integrated circuit dies 100 may be bonded to the carrier 116 and processed together during the subsequent manufacturing steps until singulated into individual package components. A bonding layer 118 may be disposed on the carrier 116. The bonding layer 118 may comprise a dielectric material, such as silicon dioxide, silicon oxynitride, or the like.

The integrated circuit die 100 may be bonded to the bonding layer 118 by placing the integrated circuit die 100 on the bonding layer 118 by a pick-and-place process or the like, then bonding the integrated circuit die 100 to the bonding layer 118. During the pick-and-place process, electrostatic charges may be generated in the substrate 102. The protective structure 101 may reduce or prevent the electrostatic charges from being released through the conductive seal ring structure 105, thereby reducing or preventing formation of cracks due to ESD in the integrated circuit die 100 and/or a gap-fill dielectric to be formed around the integrated circuit die 100 in a subsequent process. As a result, the reliability of the integrated circuit package 300 may be improved.

As an example of the bonding process, the integrated circuit die 100 may be bonded to the bonding layer 118 by dielectric-to-dielectric bonding without using any adhesive material (e.g., die attach film). The bonding process may include a pressing step and an annealing step. During the pressing step, a small pressing force may be applied to press the integrated circuit die 100 against the bonding layer 118. The pressing step may be performed at a low temperature, such as room temperature. After the pressing step, the dielectric layer 106 may be bonded to the bonding layer 118 by direct bonds, such as fusion bonds, covalent bonds, or the like. The bonding strength may be then improved in a subsequent annealing step, in which the dielectric layer 106 and the bonding layer 118 may be annealed at a higher temperature.

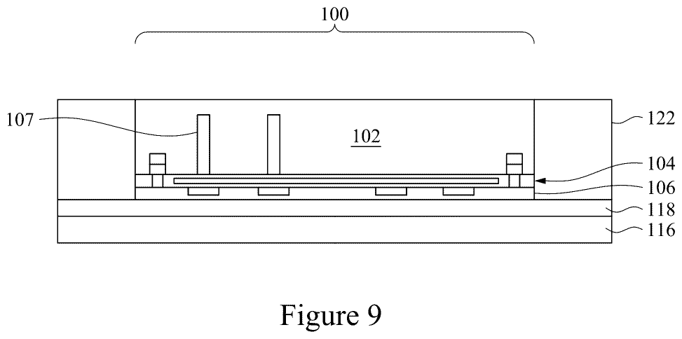

In FIG. 9, a gap-fill dielectric 122 is formed around the integrated circuit die 100 and between the neighboring integrated circuit dies 100 over the carrier 116, and the substrate 102 are thinned to expose the conductive vias 107. The gap-fill dielectric 122 may be formed of a dielectric material, such as silicon oxide, PSG, BSG, BPSG, a TEOS based oxide, or the like, which may be formed by a suitable deposition process such as CVD, ALD, or the like. Initially, the gap-fill dielectric 122 may bury or cover the back side of the integrated circuit die 100. A thinning process such as a CMP, a grinding process, an etch-back process, combinations thereof, or the like, may be performed to level surfaces of the gap-fill dielectric 122 with the back side surface of integrated circuit die 100. Then the substrate 102 may be thinned to expose the conductive vias 107. Portions of the gap-fill dielectric 122 may also be removed by the thinning process. The thinning process may be, a CMP, a grinding process, an etch-back process, combinations thereof, or the like, which is performed at the back sides of the integrated circuit die 100. After the thinning process, surfaces of the gap-fill dielectric 122 and the integrated circuit die 100 (including the substrate 102 and the conductive vias 107) may be substantially coplanar (within process variations).

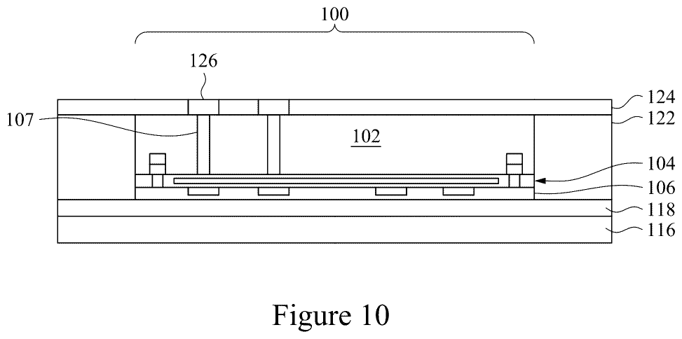

In FIG. 10, a dielectric layer 124 is formed on the gap-fill dielectric 122 and the back side of the integrated circuit die 100, and die connectors 126 are formed in the dielectric layer 124. The die connectors 126 may extend through the dielectric layer 124 and connect to the conductive vias 107. The dielectric layer 124 may electrically isolate the conductive vias 107 from one another, thus avoiding shorting, and may also be utilized in a subsequent bonding process. The dielectric layer 124 may be formed of an oxide such as silicon oxide, PSG, BSG, BPSG, a TEOS based oxide, or the like, which may be formed by a suitable deposition process such as CVD, or the like. The die connectors 126 may be formed by a damascene process, such as a single damascene process, a dual damascene process, or the like. The die connectors 126 may be formed of a metal, such as copper, aluminum, or the like, which can be formed by plating, or the like. In some embodiments, a planarization process such as a CMP, a grinding process, an etch-back process, combinations thereof, or the like, is performed on the dielectric layer 124 and the die connectors 126. After the thinning process, surfaces of the dielectric layer 124 and the die connectors 126 may be substantially coplanar (within process variations).

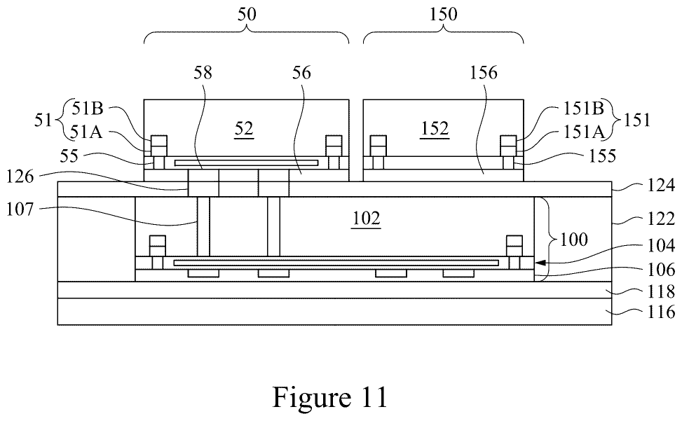

In FIG. 11, the integrated circuit die 50 is bonded to the dielectric layer 124 and the die connectors 126, and the inactive die 150 is bonded to the dielectric layer 124. The die connectors 126 electrically couple the integrated circuit die 50 and the integrated circuit die 100. The layout of the integrated circuit die 50 and the inactive die 150 on the integrated circuit die 100 shown in FIG. 11 is an example, other layouts with more integrated circuit dies 50 and no or more inactive dies 150 are contemplated.

The integrated circuit die 50 may be bonded to the dielectric layer 124 and the die connectors 126 by placing the integrated circuit die 50 on the dielectric layer 124 and the die connectors 126 by a pick-and-place process or the like, then bonding the integrated circuit die 50 to the dielectric layer 124 and the die connectors 126. During the pick-and-place process, electrostatic charges may be generated in the substrate 52. The protective structure 51 may reduce or prevent the electrostatic charges from being released through the conductive seal ring structure 55, thereby reducing or preventing formation of cracks due to ESD in the integrated circuit die 50 and/or a gap-fill dielectric to be formed around the integrated circuit die 50 in a subsequent process. As a result, the reliability of the integrated circuit package 300 may be improved.

The inactive die 150 may be bonded to the dielectric layer 124 by placing inactive die 150 on the dielectric layer 124 by a pick-and-place process or the like, then bonding the inactive die 150 to the dielectric layer 124. During the pick-and-place process, electrostatic charges may be generated in the substrate 152. The protective structure 151 may reduce or prevent the electrostatic charges from being released through the conductive seal ring structure 155, thereby reducing or preventing formation of cracks due to ESD in the inactive die 150 and/or a gap-fill dielectric to be formed around the inactive die 150 in a subsequent process. As a result, the reliability of the integrated circuit package 300 may be improved.

The dielectric layer 56 of the integrated circuit die 50 may be directly bonded to the dielectric layer 124 through dielectric-to-dielectric bonding, without using any adhesive material (e.g., die attach film). The die connectors 58 of the integrated circuit die 50 are directly bonded to respective die connectors 126 through metal-to-metal bonding, without using any eutectic material (e.g., solder). The bonding process may include a pressing step and an annealing step. During the pressing step, a small pressing force may be applied to press the integrated circuit die 50 against the dielectric layer 124 and the die connectors 126. The pressing step may be performed at a low temperature, such as room temperature. After the pressing step, the dielectric layer 56 may be bonded to the dielectric layer 124 by direct bonds, such as fusion bonds, covalent bonds, or the like. The bonding strength may be then improved in a subsequent annealing step, in which the dielectric layer 124, the die connectors 126, the dielectric layer 56, and the die connectors 58 are annealed at a higher temperature. The die connectors 126 and the die connectors 58 may be in physical contact after the pressing step, or may expand to be brought into physical contact during the annealing step. Further, during the annealing step, the materials of the die connectors 126 and the die connectors 58 may intermingle, so that metal-to-metal bonds may be formed. The die connectors 126 may be to the die connectors 58 with a one-to-one correspondence. The dielectric layer 156 of the inactive die 150 may be bonded to the dielectric layer 124 by dielectric-to-dielectric bonding without using any adhesive material (e.g., die attach film). The bonding process may be same or similar to the bonding process between the dielectric layer 56 of the integrated circuit die 50 and the dielectric layer 124 described above.

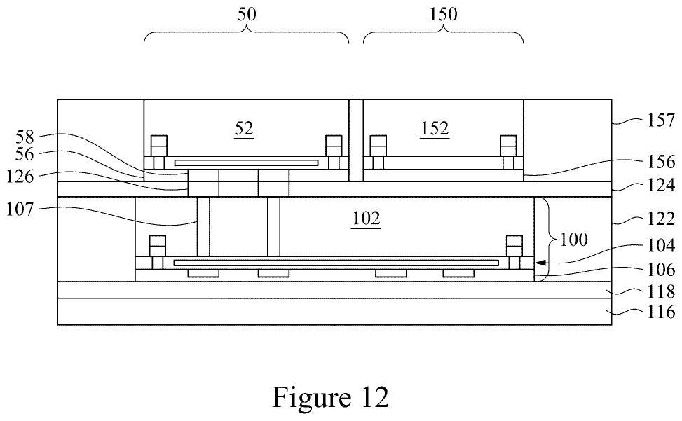

In FIG. 12, a gap-fill dielectric 157 is formed around the integrated circuit die 50, around the inactive die 150, and between the neighboring integrated circuit dies 50 and the inactive dies 150 over the dielectric layer 124. The gap-fill dielectric 157 may be formed of a dielectric material, such as silicon oxide, PSG, BSG, BPSG, a TEOS based oxide, or the like. In some embodiments, the gap-fill dielectric 157 is formed of the same dielectric material as the gap-fill dielectric 122. The gap-fill dielectric 122 may be formed by a same or similar method as the gap-fill dielectric 122. A thinning process may be performed to remove portions of the substrate 52, the substrate 152, and the gap-fill dielectric 157. The thinning process may be, a CMP, a grinding process, an etch-back process, combinations thereof, or the like, which is performed at the back sides of the integrated circuit die 50. After the thinning process, surfaces of the gap-fill dielectric 157, the integrated circuit die 50 (including the substrate 102), the inactive die 150 (including the substrate 152) may be substantially coplanar (within process variations).

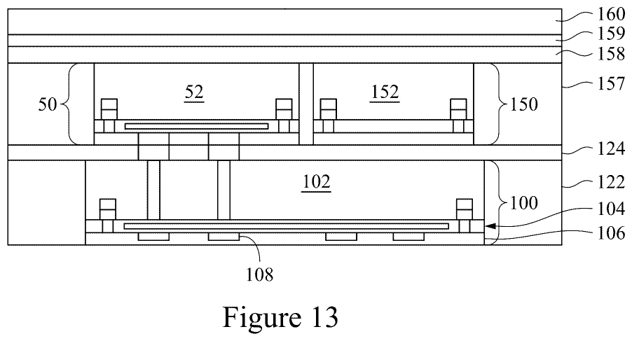

In FIG. 13, a bonding layer 158 is formed on the substrate 102, the substrate 152, and the gap-fill dielectric 157, and the structure over the carrier 116 (see FIG. 12) is bonded to a carrier 160. Then the carrier 116 and the bonding layer 118 are removed. The bonding layer 158 may comprise a dielectric material, such as silicon dioxide or the like, and may be formed by a suitable deposition process such as CVD, ALD, or the like. The carrier 160 may be a semiconductor carrier, a glass carrier, a ceramic carrier, or the like. The carrier 160 may be a wafer having a same or similar size as the carrier 116. A bonding layer 159 may be disposed on the carrier 160. The bonding layer 159 may comprise a dielectric material, such as silicon dioxide or the like. The structure over the carrier 116 may be bonded to the carrier 160 by bonding the bonding layer 158 and the bonding layer 159 by a same or similar process as used for bonding the dielectric layer 106 and the bonding layer 118. Then, the carrier 116 and the bonding layer 118 maybe removed by a thinning process. A portion of the gap-fill dielectric 122 may be also removed. The thinning process may be a CMP, a grinding process, an etch-back process, combinations thereof, or the like. After the thinning process, surfaces of the dielectric layer 106 and the gap-fill dielectric 122 may be substantially coplanar (within process variations).

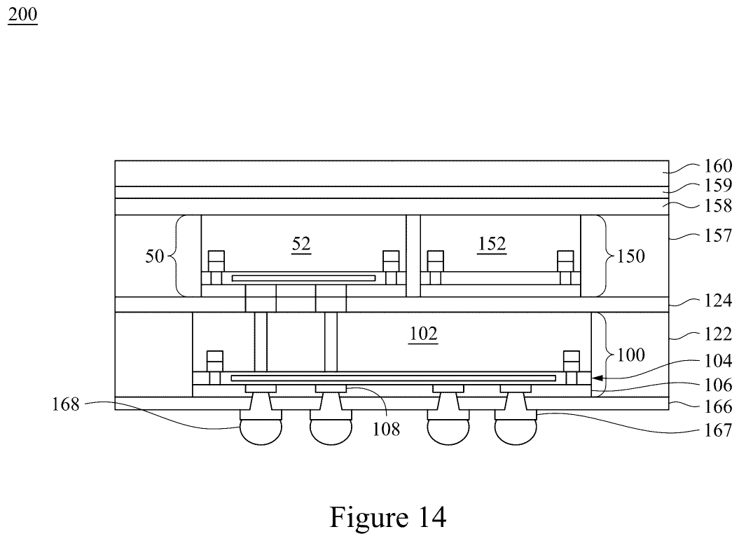

In FIG. 14, a dielectric layer 166 is formed on the dielectric layer 106 and the gap-fill dielectric 122, under-bump metallizations (UBMs) 167 are formed on and through the dielectric layer 166, and electrical connectors 168 are formed on the UBMs 167. The dielectric layer 166 may comprise silicon dioxide, silicon nitride, or the like, and may be formed by a suitable deposition process such as CVD, ALD, or the like. The dielectric layer 166 may be a passivation layer. The UBMs 167 have bump portions on and extending along a surface of the dielectric layer 166, and have via portions extending through the dielectric layer 166 and the dielectric layer 106 to physically and electrically couple to the die connectors 108. As a result, the UBMs 167 are electrically coupled to the integrated circuit die 100.

As an example to form the UBMs 167, the dielectric layer 166 and the dielectric layer 106 may be patterned to form openings exposing the underlying die connectors 108. The patterning may be done by an acceptable photolithography and etching processes, such as by forming a mask then performing an anisotropic etching. The mask may be removed after the patterning. A seed layer (not separately illustrated) may be formed on the dielectric layer 166, in the openings through the dielectric layer 166 and the dielectric layer 106, and on the exposed portions of the die connectors 108. The seed layer may be formed using a deposition process, such as physical vapor deposition (PVD) or the like. A photoresist may be then formed and patterned on the seed layer. The pattern of the photoresist may correspond to the UBMs 167. The patterning forms openings through the photoresist to expose the seed layer. A conductive material may be formed in the openings of the photoresist and on the exposed portions of the seed layer by plating, such as electroless plating or electroplating, or the like. The conductive material may comprise a metal or a metal alloy, such as copper, titanium, tungsten, aluminum, the like, or combinations thereof. Then, the photoresist and portions of the seed layer on which the conductive material is not formed may be removed by an acceptable ashing or stripping process. Once the photoresist is removed, exposed portions of the seed layer may be removed by using an acceptable etching process, such as wet or dry etching. The remaining portions of the seed layer and conductive material may be referred to as the UBMs 167.

Electrical connectors 168 may be formed on the UBMs 167. The electrical connectors 168 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The electrical connectors 168 may include a conductive material such as solder, copper, aluminum, gold, nickel, silver, palladium, tin, the like, or a combination thereof. In some embodiments, the electrical connectors 168 are formed by initially forming a layer of solder through evaporation, electroplating, printing, solder transfer, ball placement, or the like. Once a layer of solder has been formed on the structure, a reflow may be performed in order to shape the material into the desired bump shapes. In some embodiments, the electrical connectors 168 comprise metal pillars (such as a copper pillar) formed by a sputtering, printing, electroplating, electroless plating, CVD, or the like. The structure shown in FIG. 14 may be referred to as wafer structure 200.

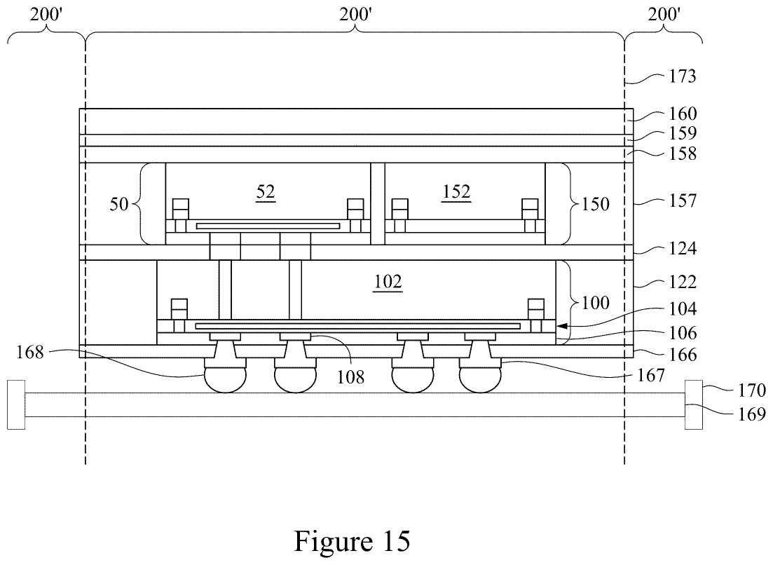

In FIG. 15, the wafer structure 200 is singulated. The wafer structure 200 may be placed on a tape 169 supported by a frame 170. The wafer structure 200 may be then singulated along scribe lines 173, so that the wafer structure 200 is separated into discrete integrated circuit package components 200′. The singulation process may include a sawing process, a laser cutting process, or the like. A cleaning process or rinsing process may be performed after the singulation process.

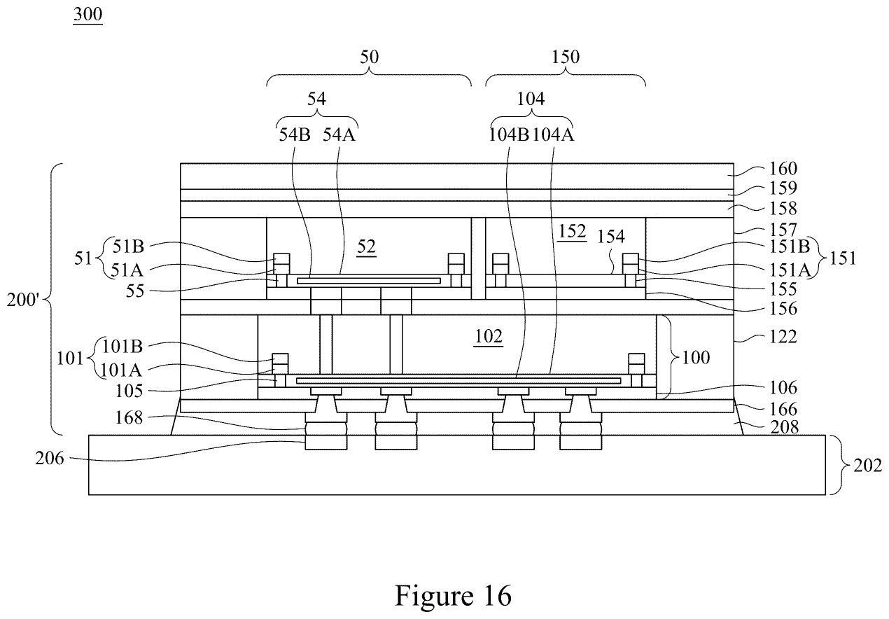

In FIG. 16, the integrated circuit package component 200′ is bonded to a package substrate 202 and an underfill 208 is formed between the integrated circuit package component 200′ and the package substrate 202. The resulting structure may be referred to as the integrated circuit package 300. The package substrate 202 may comprise conductive pads 206. In some embodiments, the package substrate 202 comprise materials such as fiberglass reinforced resin, bismaleimide-triazine (BT) resin, other printed circuit board (PCB) materials, or the like. In some embodiments, the package substrate 202 comprise materials such as silicon, germanium, silicon germanium, silicon carbide, gallium arsenic, indium arsenide, indium phosphide, silicon germanium carbide, gallium arsenic phosphide, gallium indium phosphide, or the like.

The package substrate 202 may include active and passive devices (not separately illustrated), such as transistors, capacitors, resistors, combinations thereof, or the like. The devices may be formed using any suitable methods. The package substrate 202 may comprise metallization layers and vias (not separately illustrated) physically and electrically coupled to the conductive pads 206. The metallization layers may be formed over the active and passive devices and may connect the various devices to form functional circuitry. The metallization layers may be alternating layers of dielectric material (e.g., low-k dielectric material) and conductive material (e.g., copper) with vias interconnecting the layers of conductive material. In some embodiments, the package substrate 202 is free of active and passive devices.

During the bonding process the electrical connectors 220 may be reflowed to bond the integrated circuit package component 250′ to the conductive pads 206. The electrical connectors 220 may electrically and physically couple the package substrate 202 to the integrated circuit package component 250′. In some embodiments, a solder resist (not separately illustrated) is formed on the package substrate 202. The electrical connectors 220 may be disposed in openings in the solder resist to electrically and physically couple to the conductive pads 206. The solder resist may be used to protect areas of the package substrate 202 from external damage.

The underfill 208 may be formed between the integrated circuit package component 200′ and the package substrate 202, surrounding the electrical connectors 168. The underfill 208 may reduce stress and protect the joints resulting from the reflowing of the electrical connectors 168. The underfill 208 may be formed by a capillary flow process after the integrated circuit package component 200′ is attached, or may be formed by a suitable deposition method before the integrated circuit package component 200′ is attached. The underfill 208 may be subsequently cured.

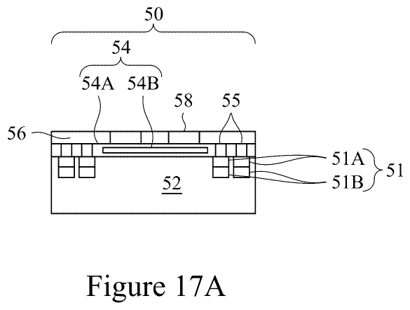

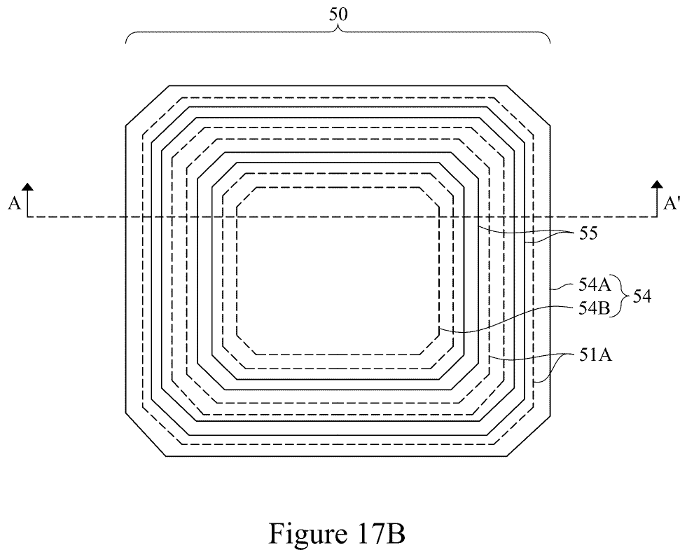

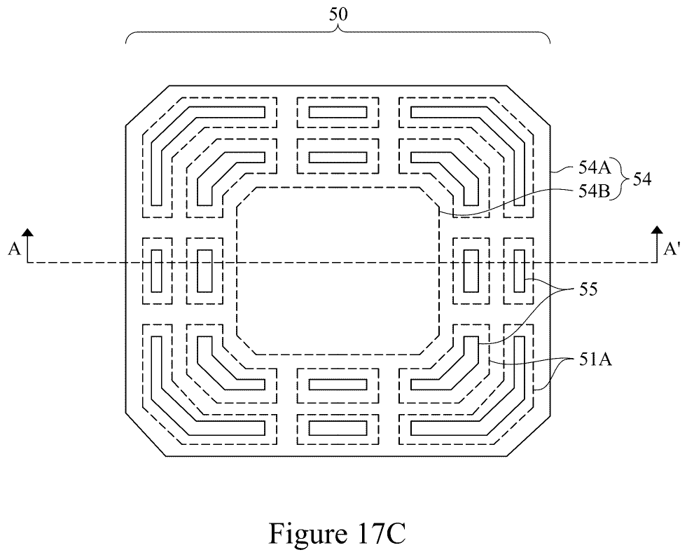

In FIGS. 17A and 17B, the integrated circuit die 50 is shown in accordance with some embodiments. The embodiments of the integrated circuit die 50 shown in FIGS. 17A and 17B may be similar to the embodiments of the integrated circuit die 50 shown in FIGS. 5A and 5B, wherein like numerals refer to like features formed by like processes. FIG. 17A is a cross-sectional view and FIG. 17B is a top-down view. The cross-sectional view in FIG. 17A may be along a reference cross-sections A-A′ shown in the top-down view of FIG. 17B. The conductive features 54B of the interconnect structure 54 and the protective structure 51 are shown in dashed lines in FIG. 17B for illustrative purposes. In the embodiments shown in FIG. 17B, the seal ring structure 55 comprises two concentric continuous rings encircling the conductive features 54B and the protective structure 51 comprises two concentric continuous rings encircling the conductive features 54B in the top-down view. The inner continuous ring of the seal ring structure 55 may be separated from the substrate 52 by the inner continuous ring of the protective structure 51. The outer continuous ring of the seal ring structure 55 may be separated from the substrate 52 by the outer continuous ring of the protective structure 51.

FIG. 17C is a top-down view of the integrated circuit die 50 in accordance with some embodiments. The embodiments of the integrated circuit die 50 shown in FIG. 17C may be similar to the embodiments of the integrated circuit die 50 shown in FIG. 17B, wherein like numerals refer to like features formed by like processes. The cross-sectional view in FIG. 17A may be along a reference cross-sections A-A′ shown in the top-down view of FIG. 17C. The conductive features 54B of the interconnect structure 54 and the protective structure 51 are shown in dashed lines in FIG. 17C for illustrative purposes. In the embodiments shown in FIG. 17C, the seal ring structure 55 comprises two concentric fragmented rings encircling the conductive features 54B and the protective structure 51 comprises two concentric fragmented rings encircling the conductive features 54B in the top-down view. The inner fragmented ring of the seal ring structure 55 may separate the inner fragmented ring of the protective structure 51 from the substrate 52. The outer fragmented ring of the seal ring structure 55 may separate the outer fragmented ring of the protective structure 51 from the substrate 52.

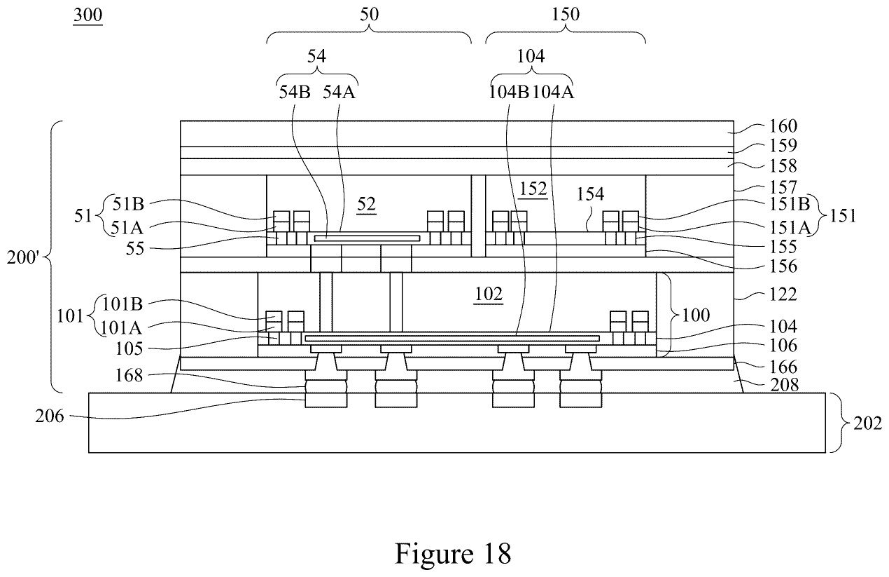

FIG. 18 shows the integrated circuit package 300 in accordance with some embodiments. The embodiments of the integrated circuit package 300 shown in FIG. 18 may be similar to the embodiments of the integrated circuit package 300 shown in FIG. 16, wherein like numerals refer to like features formed by like processes. In the embodiments shown in FIG. 18, the integrated circuit package 300 comprises the integrated circuit die 50 shown in FIGS. 17A, 17B, and 17C. The integrated circuit package 300 may comprise the integrated circuit die 100 with the seal ring structure 105 and the protective structure 101 similar to the seal ring structure 55 and the protective structure 51, respectively, as shown in FIGS. 17A, 17B, and 17C. The integrated circuit package 300 may comprise the inactive die 150 with the seal ring structure 155 and the protective structure 151 similar to the seal ring structure 55 and the protective structure 51, respectively, as shown in FIGS. 17A, 17B, and 17C.

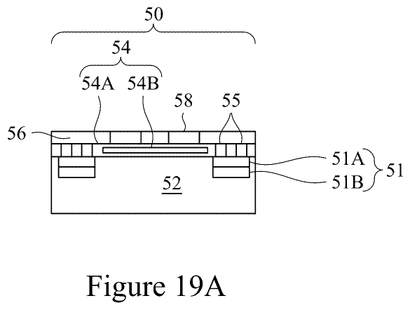

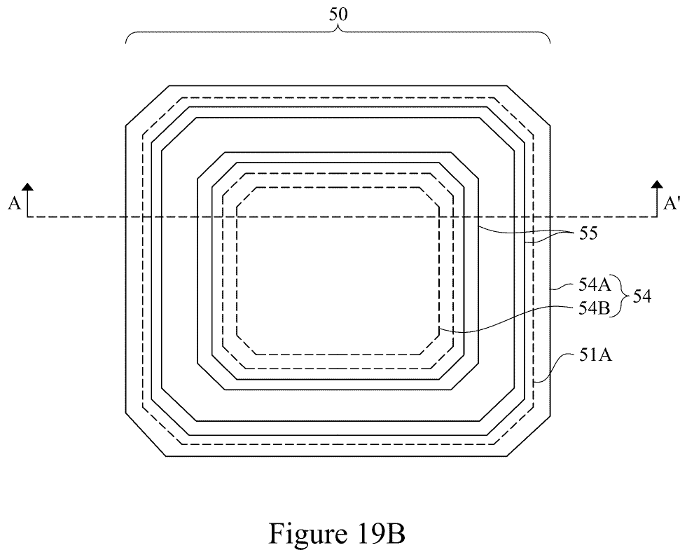

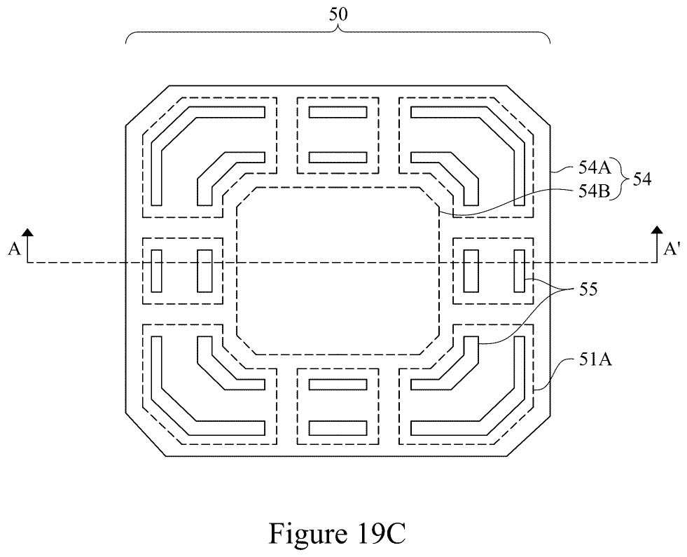

In FIGS. 19A and 19B, the integrated circuit die 50 is shown in accordance with some embodiments. The embodiments of the integrated circuit die 50 shown in FIGS. 19A and 19B may be similar to the embodiments of the integrated circuit die 50 shown in FIGS. 17A and 17B, wherein like numerals refer to like features formed by like processes. FIG. 19A is a cross-sectional view and FIG. 19B is a top-down view. The cross-sectional view in FIG. 19A may be along a reference cross-sections A-A′ shown in the top-down view of FIG. 19B. The conductive features 54B of the interconnect structure 54 and the protective structure 51 are shown in dashed lines in FIG. 19B for illustrative purposes. In the embodiments shown in FIG. 19B, the seal ring structure 55 comprises two concentric continuous rings encircling the conductive features 54B and the protective structure 51 comprises a continuous ring encircling the conductive features 54B in the top-down view. The two concentric continuous rings of the seal ring structure 55 may be separated from the substrate 52 by the continuous ring of the protective structure 51.

FIG. 19C is a top-down view of the integrated circuit die 50 in accordance with some embodiments. The embodiments of the integrated circuit die 50 shown in FIG. 19C may be similar to the embodiments of the integrated circuit die 50 shown in FIG. 19B, wherein like numerals refer to like features formed by like processes. The cross-sectional view in FIG. 19A may be along a reference cross-sections A-A′ shown in the top-down view of FIG. 19C. The conductive features 54B of the interconnect structure 54 and the protective structure 51 are shown in dashed lines in FIG. 19C for illustrative purposes. In the embodiments shown in FIG. 19C, the seal ring structure 55 comprises two concentric fragmented rings encircling the conductive features 54B and the protective structure 51 comprises a fragmented ring encircling the conductive features 54B in the top-down view. The two concentric fragmented rings of the seal ring structure 55 may be separated from the substrate 52 by the fragmented ring of the protective structure 51.

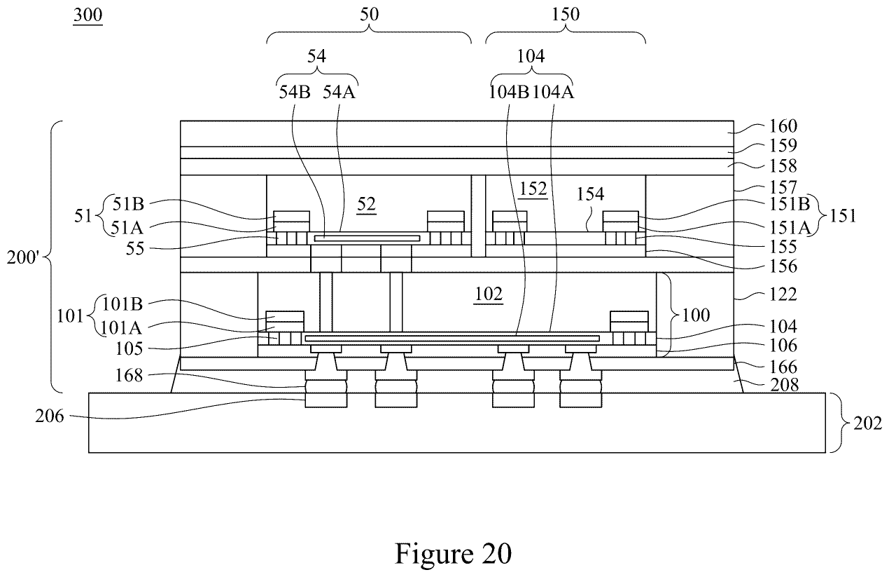

FIG. 20 shows the integrated circuit package 300 in accordance with some embodiments. The embodiments of the integrated circuit package 300 shown in FIG. 20 may be similar to the embodiments of the integrated circuit package 300 shown in FIG. 18, wherein like numerals refer to like features formed by like processes. In the embodiments shown in FIG. 20, the integrated circuit package 300 comprises the integrated circuit die 50 shown in FIGS. 19A, 19B, and 19C. The integrated circuit package 300 may comprise the integrated circuit die 100 with the seal ring structure 105 and the protective structure 101 similar to the seal ring structure 55 and the protective structure 51, respectively, as shown in FIGS. 19A, 19B, and 19C. The integrated circuit package 300 may comprise the inactive die 150 with the seal ring structure 155 and the protective structure 151 similar to the seal ring structure 55 and the protective structure 51, respectively, as shown in FIGS. 19A, 19B, and 19C.

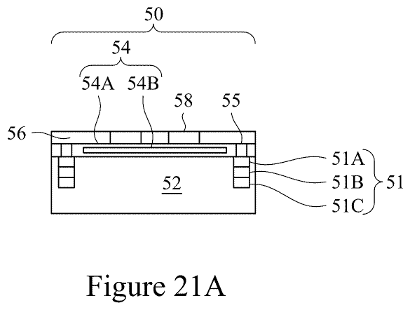

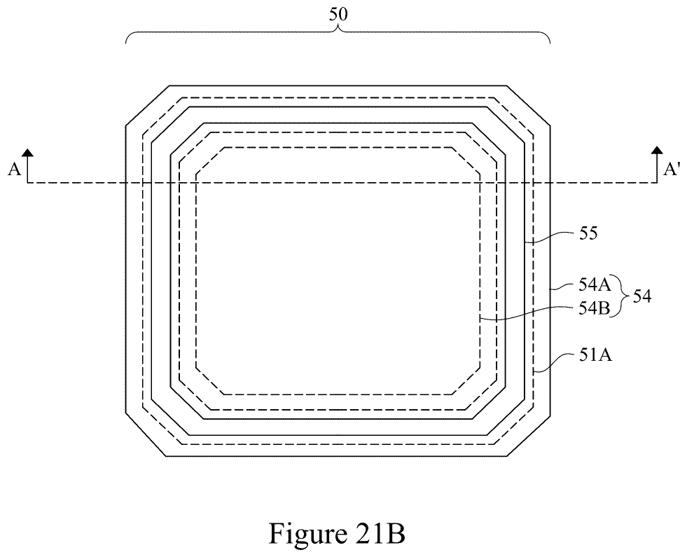

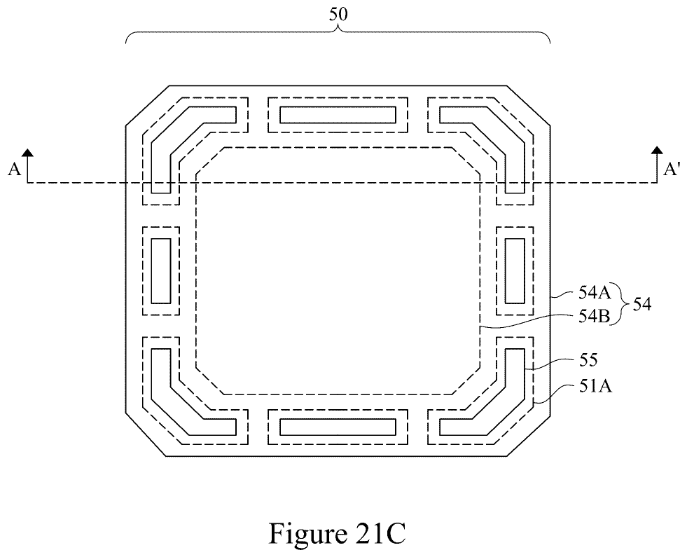

In FIGS. 21A and 21B, the integrated circuit die 50 is shown in accordance with some embodiments. The embodiments of the integrated circuit die 50 shown in FIGS. 21A and 21B may be similar to the embodiments of the integrated circuit die 50 shown in FIGS. 5A and 5B, wherein like numerals refer to like features formed by like processes. FIG. 21A is a cross-sectional view and FIG. 21B is a top-down view. The cross-sectional view in FIG. 21A may be along a reference cross-sections A-A′ shown in the top-down view of FIG. 21B. The conductive features 54B of the interconnect structure 54 and the protective structure 51 are shown in dashed lines in FIG. 21B for illustrative purposes.

In the embodiments shown in FIG. 21A, the protective structure 51 further comprises a third portion 51C in addition to the first portion 51A and the second portion 51B. The second portion 51B may be between the first portion 51A and the third portion 51C. The second portion 51B may separate the first portion 51A from the third portion 51C. The third portion 51C may comprise a seventh dopant. The seventh dopant may be different from the second dopant. The seventh dopant and the second dopant may be of different conductivity types, and p-n junction may be formed at an interface between the third portion 51C and the second portion 51B. The seventh dopant and the first dopant may be of the same conductivity type. In some embodiments, the seventh dopant is same as the first dopant. In some embodiments, the first dopant and the seventh dopant may be n-type dopants, such as phosphor, arsenic, or the like, and the second dopant may be a p-type dopant, such as boron, aluminum, gallium, indium, or the like. In some embodiments, the first dopant and the seventh dopant may be p-type dopants, such as boron, aluminum, gallium, indium, or the like, and the second dopant may be an n-type dopant, such as phosphor, arsenic, or the like.

FIG. 21C is a top-down view of the integrated circuit die 50 in accordance with some embodiments. The embodiments of the integrated circuit die 50 shown in FIG. 21C may be similar to the embodiments of the integrated circuit die 50 shown in FIG. 21B, wherein like numerals refer to like features formed by like processes. The cross-sectional view in FIG. 21A may be along a reference cross-sections A-A′ shown in the top-down view of FIG. 21C. The conductive features 54B of the interconnect structure 54 and the protective structure 51 are shown in dashed lines in FIG. 21C for illustrative purposes. In the embodiments shown in FIG. 21C, the seal ring structure 55 comprises a fragmented ring encircling the conductive features 54B and the protective structure 51 comprises a fragmented ring encircling the conductive features 54B in the top-down view.

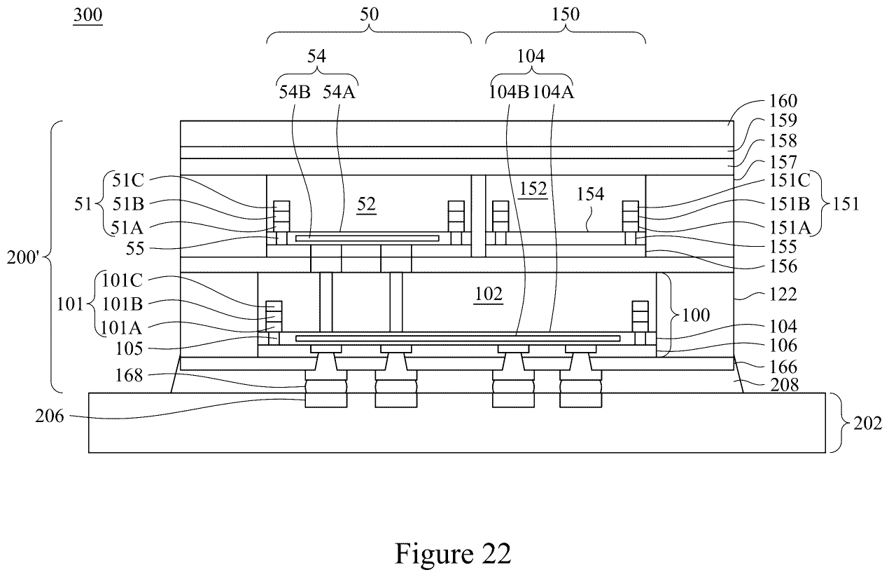

FIG. 22 shows the integrated circuit package 300 in accordance with some embodiments. The embodiments of the integrated circuit package 300 shown in FIG. 22 may be similar to the embodiments of the integrated circuit package 300 shown in FIG. 16, wherein like numerals refer to like features formed by like processes. In the embodiments shown in FIG. 22, the integrated circuit package 300 comprises the integrated circuit die 50 shown in FIGS. 21A, 21B, and 21C. The integrated circuit package 300 may comprise the integrated circuit die 100 with the seal ring structure 105 and the protective structure 101 similar to the seal ring structure 55 and the protective structure 51, respectively, as shown in FIGS. 21A, 21B, and 21C. The integrated circuit package 300 may comprise the inactive die 150 with the seal ring structure 155 and the protective structure 151 similar to the seal ring structure 55 and the protective structure 51, respectively, as shown in FIGS. 21A, 21B, and 21C.

The embodiments of the present disclosure have some advantageous features. By forming the protective structure 51 in the integrated circuit die 50, the protective structure 101 in the integrated circuit die 100, and the protective structure 151 in the inactive die 150, the formation of cracks due to ESD in integrated circuit die 50, the integrated circuit die 100, the inactive die 150, the gap-fill dielectric 122, and/or the gap-fill dielectric 157 may be reduced or prevented. As a result, the reliability of the integrated circuit package 300 may be improved.

In an embodiment, an integrated circuit package includes an integrated circuit die including: a substrate; a protective structure in the substrate, wherein the protective structure and the substrate include a same semiconductor material, and wherein the protective structure includes a first dopant and a second dopant different from the first dopant; an interconnect structure on the substrate, wherein the interconnect structure includes dielectric layers and conductive features in the dielectric layers; a seal ring structure in the dielectric layers of the interconnect structure, wherein the seal ring structure encircles the conductive features of the interconnect structure in a top-down view, and wherein the seal ring structure is in contact with the protective structure; and a dielectric material on sidewalls of the integrated circuit die. In an embodiment, the protective structure includes a p-n junction. In an embodiment, the protective structure includes a first portion including the first dopant and a second portion including the second dopant, wherein the first portion of the protective structure is in contact with the protective structure, and wherein the second portion of the protective structure is separated from the seal ring structure by the first portion of the protective structure. In an embodiment, the first dopant and the second dopant are of different conductivity types. In an embodiment, the protective structure includes a first portion including the first dopant, a second portion including the second dopant, and a third portion including a third dopant different from the second dopant. In an embodiment, the first portion of the protective structure is in contact with the protective structure, wherein the second portion of the protective structure is separated from the seal ring structure by the first portion of the protective structure, and wherein the third portion of the protective structure is separated from the first portion of the protective structure by the second portion of the protective structure. In an embodiment, the first dopant and the second dopant are of different conductivity types, and wherein the first dopant and the third dopant are of a same conductivity type. In an embodiment, the seal ring structure is separated from the substrate by the protective structure.

In an embodiment, an integrated circuit package includes an integrated circuit die including: a substrate, wherein the substrate includes a first semiconductor material; a protective structure in the substrate, wherein the protective structure includes the first semiconductor material, wherein a first portion of the protective structure is doped with a first dopant and a second portion of the protective structure is doped with a second dopant, and wherein the first dopant and the second dopant are of different conductivity types; an interconnect structure on the substrate, wherein the interconnect structure includes dielectric layers and conductive features in the dielectric layers; a seal ring structure in the dielectric layers of the interconnect structure, wherein the seal ring structure is in contact with the first portion of the protective structure; and a dielectric material on sidewalls of the integrated circuit die. In an embodiment, the seal ring structure is separated from the second portion of the protective structure by the first portion of the protective structure. In an embodiment, the seal ring structure is narrower than the first portion of the protective structure. In an embodiment, the seal ring structure is a continuous ring encircling the conductive features of the interconnect structure in a top-down view, and wherein the protective structure is a continuous ring encircling the conductive features of the interconnect structure in the top-down view. In an embodiment, the seal ring structure is a fragmented ring encircling the conductive features of the interconnect structure in a top-down view, and wherein the protective structure is a fragmented ring encircling the conductive features of the interconnect structure in the top-down view. In an embodiment, the protective structure further includes a third portion doped with the first dopant, and wherein the second portion of the protective structure is between the first portion of the protective structure and the third portion of the protective structure.

In an embodiment, a method includes forming a protective structure in a substrate by sequentially doping the substrate with a first dopant and a second dopant, wherein the second dopant is different from the first dopant, and wherein the protective structure includes a first portion including the first dopant and a second portion including the second dopant; forming an interconnect structure on a first portion of the substrate, wherein the interconnect structure includes dielectric layers and conductive features in the dielectric layers; forming a seal ring structure in the dielectric layers of the interconnect structure, wherein the seal ring structure encircles the conductive features of the interconnect structure in a top-down view, wherein the seal ring structure is in contact with the second portion of the protective structure, and wherein the seal ring structure is separated from the first portion of the substrate by the second portion of the protective structure; singulating the substrate to form an integrated circuit die, wherein the integrated circuit die includes the first portion of the substrate, the protective structure, the interconnect structure, and the seal ring structure; and forming an integrated circuit package with the integrated circuit die. In an embodiment, the first portion of the protective structure is separated from the seal ring structure by the second portion of the protective structure. In an embodiment, the first portion of the protective structure is in contact with the dielectric layers of the interconnect structure. In an embodiment, the protective structure includes a p-n junction at an interface between the first portion of the protective structure and the second portion of the protective structure. In an embodiment, the protective structure is spaced apart from sidewalls of the first portion of the substrate. In an embodiment, the protective structure is isolated from circuitry of the integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package comprising:
an integrated circuit die comprising:
a substrate;
a protective structure in the substrate, wherein the protective structure and the substrate comprise a same semiconductor material, and wherein the protective structure comprises a first dopant and a second dopant different from the first dopant;
an interconnect structure on the substrate, wherein the interconnect structure comprises dielectric layers and conductive features in the dielectric layers;
a seal ring structure in the dielectric layers of the interconnect structure, wherein the seal ring structure encircles the conductive features of the interconnect structure in a top-down view, and wherein the seal ring structure is in contact with the protective structure; and
a dielectric material on sidewalls of the integrated circuit die.

2. The integrated circuit package of claim 1, wherein the protective structure comprises a p-n junction.

3. The integrated circuit package of claim 1, wherein the protective structure comprises a first portion comprising the first dopant and a second portion comprising the second dopant, wherein the first portion of the protective structure is in contact with the protective structure, and wherein the second portion of the protective structure is separated from the seal ring structure by the first portion of the protective structure.

4. The integrated circuit package of claim 3, wherein the first dopant and the second dopant are of different conductivity types.

5. The integrated circuit package of claim 1, wherein the protective structure comprises a first portion comprising the first dopant, a second portion comprising the second dopant, and a third portion comprising a third dopant different from the second dopant.

6. The integrated circuit package of claim 5, wherein the first portion of the protective structure is in contact with the protective structure, wherein the second portion of the protective structure is separated from the seal ring structure by the first portion of the protective structure, and wherein the third portion of the protective structure is separated from the first portion of the protective structure by the second portion of the protective structure.

7. The integrated circuit package of claim 6, wherein the first dopant and the second dopant are of different conductivity types, and wherein the first dopant and the third dopant are of a same conductivity type.

8. The integrated circuit package of claim 1, wherein the seal ring structure is separated from the substrate by the protective structure.

9. An integrated circuit package comprising:
an integrated circuit die comprising:
a substrate, wherein the substrate comprises a first semiconductor material;
a protective structure in the substrate, wherein the protective structure comprises the first semiconductor material, wherein a first portion of the protective structure is doped with a first dopant and a second portion of the protective structure is doped with a second dopant, and wherein the first dopant and the second dopant are of different conductivity types;
an interconnect structure on the substrate, wherein the interconnect structure comprises dielectric layers and conductive features in the dielectric layers;
a seal ring structure in the dielectric layers of the interconnect structure, wherein the seal ring structure is in contact with the first portion of the protective structure; and
a dielectric material on sidewalls of the integrated circuit die.

10. The integrated circuit package of claim 9, wherein the seal ring structure is separated from the second portion of the protective structure by the first portion of the protective structure.

11. The integrated circuit package of claim 9, wherein the seal ring structure is narrower than the first portion of the protective structure.

12. The integrated circuit package of claim 9, wherein the seal ring structure is a continuous ring encircling the conductive features of the interconnect structure in a top-down view, and wherein the protective structure is a continuous ring encircling the conductive features of the interconnect structure in the top-down view.

13. The integrated circuit package of claim 9, wherein the seal ring structure is a fragmented ring encircling the conductive features of the interconnect structure in a top-down view, and wherein the protective structure is a fragmented ring encircling the conductive features of the interconnect structure in the top-down view.

14. The integrated circuit package of claim 9, wherein the protective structure further comprises a third portion doped with the first dopant, and wherein the second portion of the protective structure is between the first portion of the protective structure and the third portion of the protective structure.

15. A method comprising:
forming a protective structure in a substrate by sequentially doping the substrate with a first dopant and a second dopant, wherein the second dopant is different from the first dopant, and wherein the protective structure comprises a first portion comprising the first dopant and a second portion comprising the second dopant;
forming an interconnect structure on a first portion of the substrate, wherein the interconnect structure comprises dielectric layers and conductive features in the dielectric layers;
forming a seal ring structure in the dielectric layers of the interconnect structure, wherein the seal ring structure encircles the conductive features of the interconnect structure in a top-down view, wherein the seal ring structure is in contact with the second portion of the protective structure, and wherein the seal ring structure is separated from the first portion of the substrate by the second portion of the protective structure;
singulating the substrate to form an integrated circuit die, wherein the integrated circuit die comprises the first portion of the substrate, the protective structure, the interconnect structure, and the seal ring structure; and
forming an integrated circuit package with the integrated circuit die.

16. The method of claim 15, wherein the first portion of the protective structure is separated from the seal ring structure by the second portion of the protective structure.

17. The method of claim 15, wherein the first portion of the protective structure is in contact with the dielectric layers of the interconnect structure.

18. The method of claim 15, wherein the protective structure comprises a p-n junction at an interface between the first portion of the protective structure and the second portion of the protective structure.

19. The method of claim 15, wherein the protective structure is spaced apart from sidewalls of the first portion of the substrate.

20. The method of claim 15, wherein the protective structure is isolated from circuitry of the integrated circuit die.
